(19) United States
(12) Patent Application Publication
(10) Pub. No.: US 2024/0266209 A1
(43) Pub. Date: Aug. 8, 2024

(54) SEMICONDUCTOR DEVICE AND METHOD OF MAKING THE SAME

(71) Applicant: TAIWAN SEMICONDUCTOR MANUFACTURING COMPANY, LTD., Hsinchu (TW)

(72) Inventors: Chih-Han LIN, Hsinchu city (TW); Kuei-Yu KAO, Hsinchu (TW); Shih-Yao LIN, New Taipei City (TW); Ke-Chia TSENG, Hsinchu City (TW); Min Chiao LIN, Hsinchu City (TW); Hsien-Chung HUANG, Hsinchu (TW); Chun-Hung CHEN, Hsinchu County (TW); Guan Kai HUANG, Changhua County (TW); Chao-Cheng CHEN, Hsin-Chu City (TW); Chen-Ping CHEN, Yilan County (TW); Ming-Ching CHANG, Hsinchu City (TW)

(21) Appl. No.: 18/105,659

(22) Filed: Feb. 3, 2023

(51) Int. Cl. H01L 21/762; H01L 21/8238; H01L 27/088

(52) U.S. Cl. CPC H01L 21/76224; H01L 21/823878; H01L 27/0886; H01L 27/0924

(57) ABSTRACT

A semiconductor device includes a fin extending from a substrate and including a first fin end, a separation structure separating the first fin end from an adjacent fin end of another fin, a dummy gate spacer along sidewalls of the separation structure and the fin, a first epitaxial source/drain region in the fin and adjacent the separation structure, and a residue of a dummy gate material in a corner region between the dummy gate spacer and the first fin end. The first fin end protrudes from the dummy gate spacer into the separation structure. The residue of the dummy gate material separates the first epitaxial source/drain region from the separation structure and is triangle shaped.

### BACKGROUND

As the semiconductor industry has progressed into nanometer technology process nodes in pursuit of higher device density, greater performance, and lower costs, challenges for both design and fabrication of integrated circuits have greatly increased. Due to continually reduced critical dimensions, more issues arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a fin field effect transistor (FinFET) in a three-dimensional view in accordance with some embodiments.

FIGS. 2, 3, 4, 5, 6, 7, 8A, 8B, 8C, 9A, 9B, 9C, 10A, 10B, 10C, 10D, 10E, 10F, 11A, 11B, 12A, 12B, 12C, 13A, 13B, 13C, 13D, 13E, 14A, 14B, 14C, 14D, 14E, 15A, 15B, 15C, 15D, 16A, 16B, 17A, 17B, 17C, 18A, 18B, 19A and 19B are cross-sectional views or plan views of various intermediate stages in sequential manufacturing operations of FinFETs in accordance with some embodiments.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity. In the accompanying drawings, some layers/features may be omitted for simplification.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” Further, in the following fabrication process, there may be one or more additional operations in/between the described operations, and the order of operations may be changed. In the following embodiments, the term “upper” “over” and/or “above” are defined along directions with an increase in a distance from the front surface and the back surface. Materials, configurations, dimensions, processes and/or operations as explained with respect to one embodiment may be employed in the other embodiments, and the detailed description thereon may be omitted. Source/drain region(s) may refer to a source or a drain, individually or collectively dependent upon the context.

With technical developments in integrated circuit (IC) and semiconductor industries, sizes of semiconductor devices are greatly reduced to increase integration density, improve performance, and reduce costs. However, as sizes of semiconductor devices continue to decrease, there are issues or risks of reduced process window, lowered yield, and poor performance of the semiconductor devices.

The present disclosure generally relates to a semiconductor device, such as a fin field effect transistor (FinFET), which includes a fin extending from a substrate and including a fin end, a separation structure separating the fin end from an adjacent fin end of another fin, a spacer along a first sidewall of the separation structure and a sidewall of the fin, a first epitaxial source/drain region in the fin and adjacent the separation structure, and a residue of a dummy gate material in a corner region between the spacer and the fin end. The fin end protrudes from the spacer into the separation structure. The residue of the dummy gate material separates the first epitaxial source/drain region from the separation structure. The dummy gate material includes silicon, silicon oxide, silicon nitride, or a combination thereof, and the like. A side of residue of the dummy gate material adjacent the separation structure forms a first angle in plan view in a range from about 5° to about 80° with respect to the sidewall of the fin. A base width of the triangle shaped dummy gate material is in a range from about 1 nm to about 100 nm, and wherein a height of the triangle shaped dummy gate material is in a range from about 1 nm to about 100 nm. A ratio of a width of the separation structure to a base width of the triangle shaped dummy gate material is in a range from about 0.03 to about 600.

In addition, the present disclosure generally relates to a method of forming a semiconductor device, the method includes forming a fin including an upper region on a substrate, forming a first isolation region surrounding the fin, forming a dummy gate structure extending over the first isolation region and an upper region, forming a spacer layer on sidewalls of the dummy gate structure and the upper region, and epitaxially growing a source/drain region adjacent the upper region, performing an etching process on the dummy gate structure to form a recess in and through the dummy gate structure and to cut the upper region underlying the dummy gate structure, and forming a separation structure in the recess. After performing the etching process, a fin end of the upper region is formed and protrudes beyond the spacer layer into the recess along a fin extending direction, and portions of the dummy gate material remain in corner regions defined by the spacer layer and the fin cut end of the upper region. The remaining portions of the dummy gate material separate portions of the separation structure from the epitaxial source/drain region.

The presence of the remaining portions of the dummy gate material increases the distance between the epitaxial source/drain regions and the separation structure, reduces the risk of damaging the epitaxial source/drain regions when forming the separation structure, thereby advantageously increasing the available process distance window, enhancing yield, and improving performance of the semiconductor device.

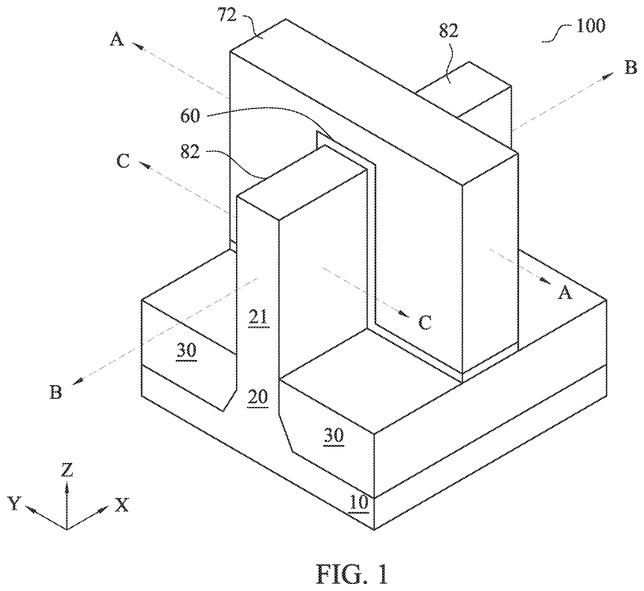

FIG. 1 illustrates an example of a semiconductor device (such as a FinFET) 100 in a three-dimensional (3D) view in accordance with some embodiments. The semiconductor device 100 includes a fin 20 on or protruding from a semiconductor substrate 10. Isolation regions 30 are disposed in the substrate 10, and the fin 20 protrudes above and from between neighboring isolation regions 30. Although only a single fin 20 is illustrated in FIG. 1, there are a plurality of fins 20 in the semiconductor device 100 in some embodiments. In this context, the fin 20 refers to the portion extending between the neighboring isolation regions 30. A gate dielectric layer 60 is over a top surface and sidewalls of the fin 20, and a gate electrode 72 is over the gate dielectric layer 60. Source/drain regions 82 are disposed in opposite sides of the fin 20 with respect to the gate dielectric layer 60 and the gate electrode 72. In some embodiments, the source/drain region 82 includes one or more epitaxial layers made of different materials than the fin under the gate electrode.

FIG. 1 further illustrates cross-section lines that are used in later figures. Cross-section line A-A is along a longitudinal axis of the gate electrode 72 and in a direction perpendicular to a current flow direction between the source/drain regions 82. Cross-section line B-B is along a longitudinal axis of the fin 20 and in the current flow direction between the source/drain regions 82 and is perpendicular to cross-section line A-A. Cross-section line C-C is parallel to cross-section line A-A and extends through a source/drain region 82. Subsequent figures refer to these cross-section lines for clarity. The semiconductor device 100 includes a FinFET in some embodiments. The technologies disclosed herein can be applied to other FETs, such as, a gate-all-around (GAA) FET, a nanosheet FET, and a fork-sheet FET.

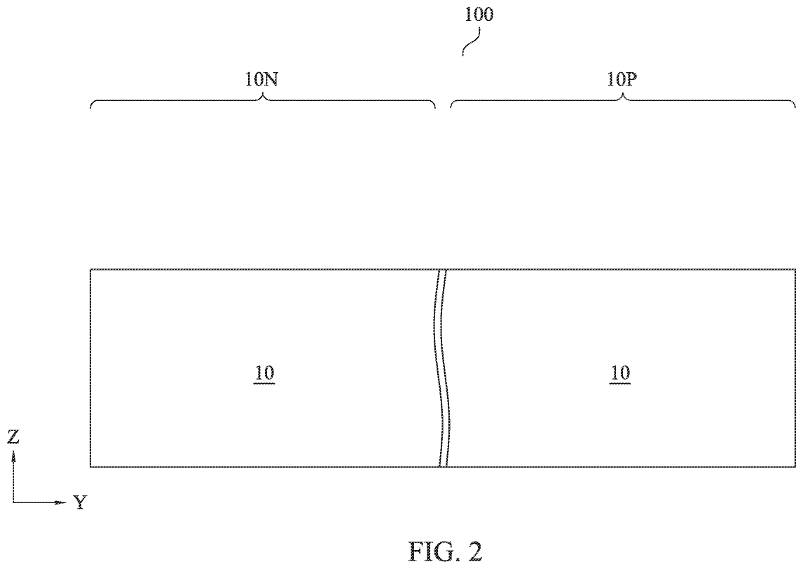

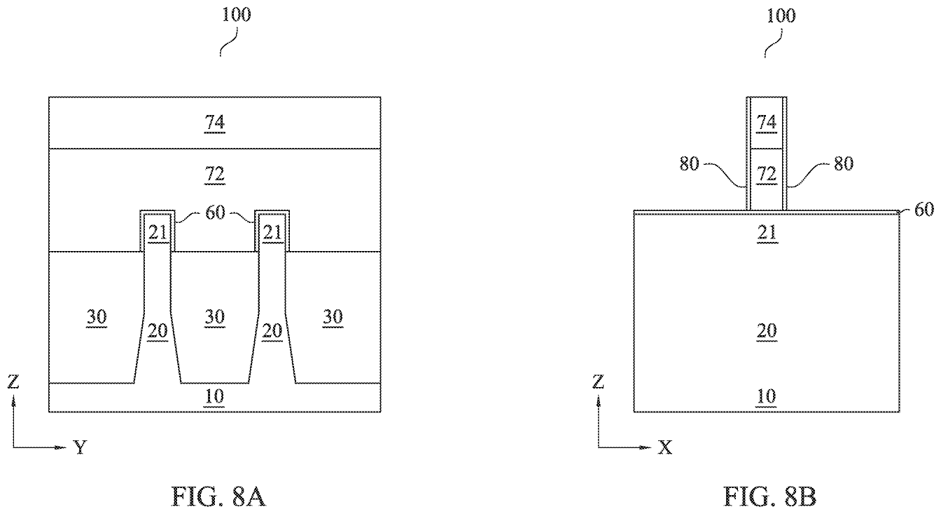

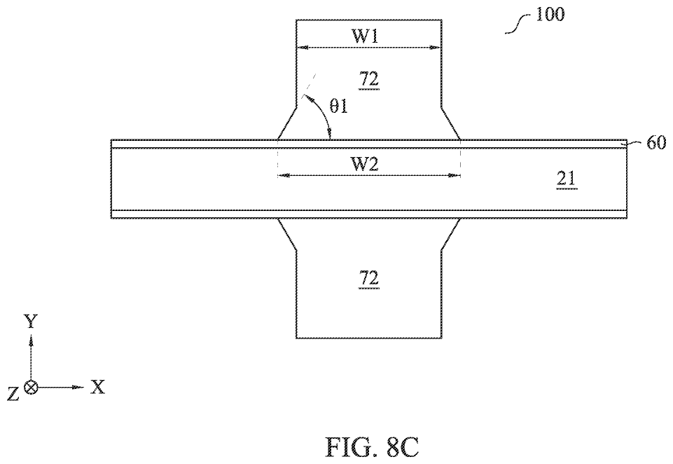

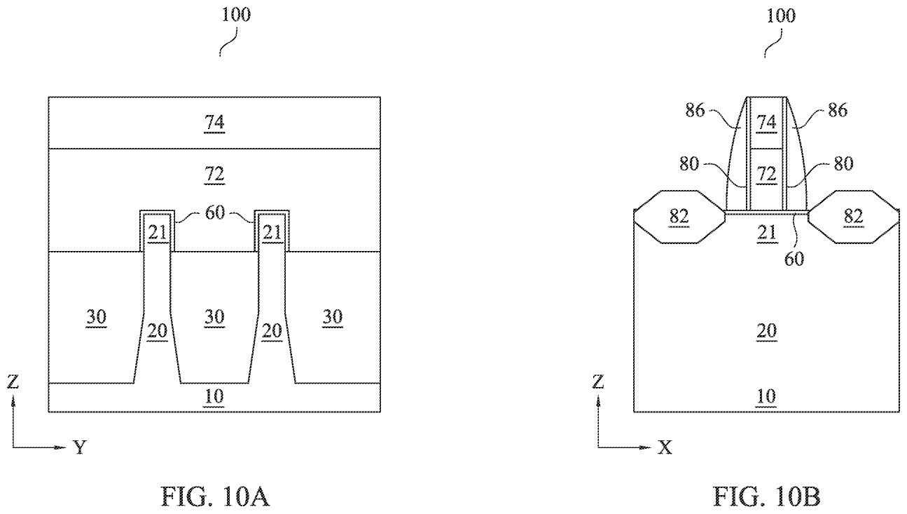

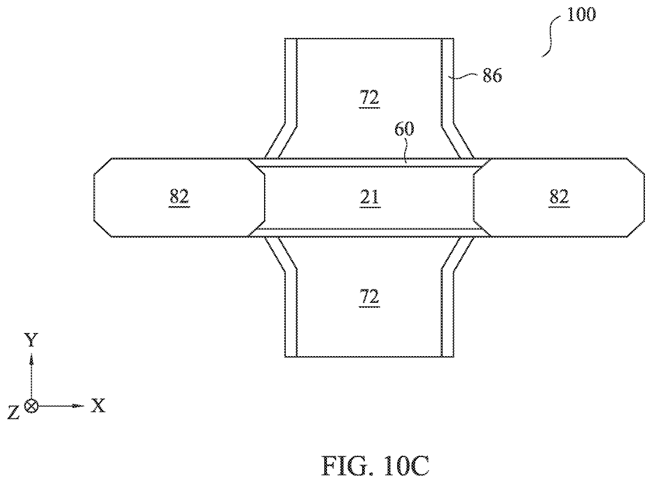

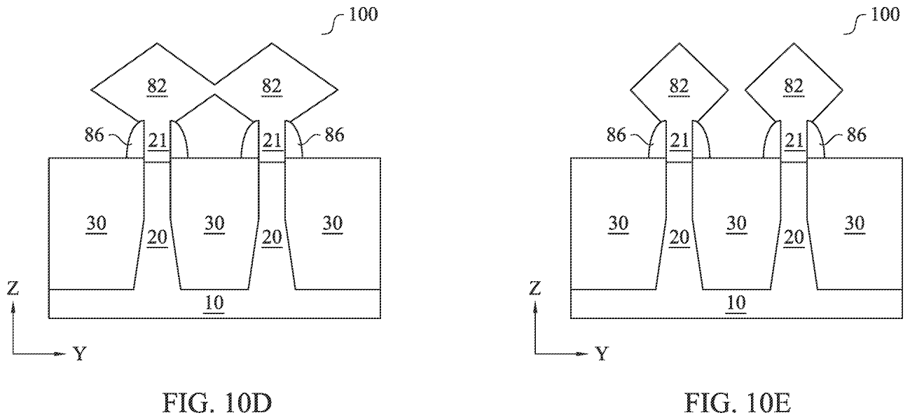

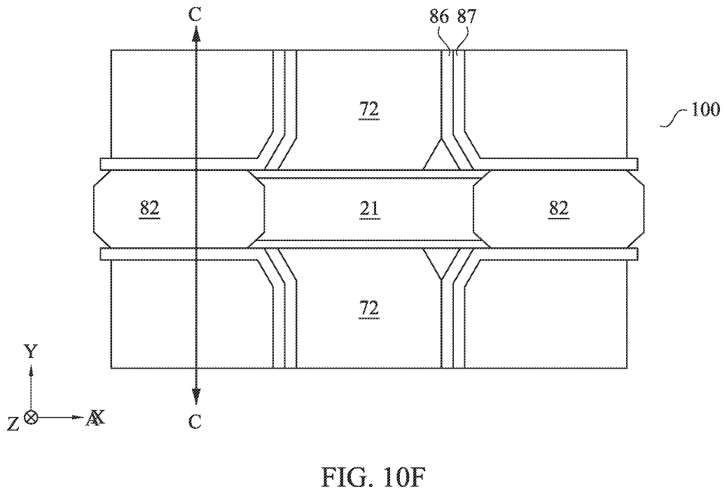

FIGS. 2 through 19B are cross-sectional views or plan views of intermediate stages in the manufacturing of FinFETs in accordance with some embodiments. It is understood that additional operations can be provided before, during, and after processes shown by FIGS. 2-19B, and some of the operations described below can be replaced or eliminated, for additional embodiments of the method. The order of the operations/processes may be interchangeable. In FIGS. 2-19B, FIGS. 2 through 7 illustrate cross-sectional views along cross-section line A-A illustrated in FIG. 1. FIGS. 8A, 9A, 10A, 11A, 12A, 13A, 14A, 15A, 16A, 17A, 18A and 19A are views along cross-section line A-A illustrated in FIG. 1. FIGS. 8B, 9B, 10B, 11B, 12B, 13B, 14B, 14E, 15B, 17B, 18B and 19B are views along cross-section line B-B illustrated in FIG. 1. FIGS. 10D and 10E are views along cross-section line C-C illustrated in FIG. 1. FIGS. 8C, 9C, 10C, 12C, 13C, 14C, 15D and 16B are illustrated in plan views or projected views, in which one or more layers or elements are omitted or illustrated as transparent.

In FIG. 2, a substrate 10 is provided. The substrate 10 is a semiconductor substrate, such as a bulk semiconductor, a semiconductor-on-insulator (SOI) substrate, or the like, which is doped (e.g., with a p-type or an n-type dopant) or undoped in some embodiments. The substrate 10 has a region 10N and a region 10P. The region 10N can be for forming n-type devices, such as NMOS transistors, e.g., n-type FinFETs. The region 10P can be for forming p-type devices, such as PMOS transistors, e.g., p-type FinFETs. The region 10N is physically and/or electrically separated from the region 10P (as illustrated by divider 11, such as an isolation structure), and any number of device features (e.g., other active devices, doped regions, isolation structures, etc.) are disposed between the region 10N and the region 10P in some embodiments.

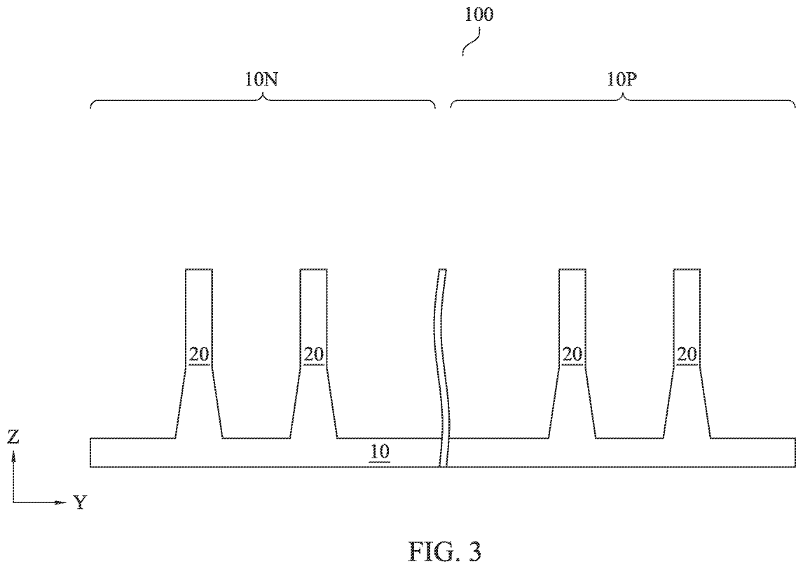

In FIG. 3, fins 20 are formed in the substrate 10. The fins 20 are semiconductor strips. The fin 20 can be patterned by any suitable method. For example, the fin structures can be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

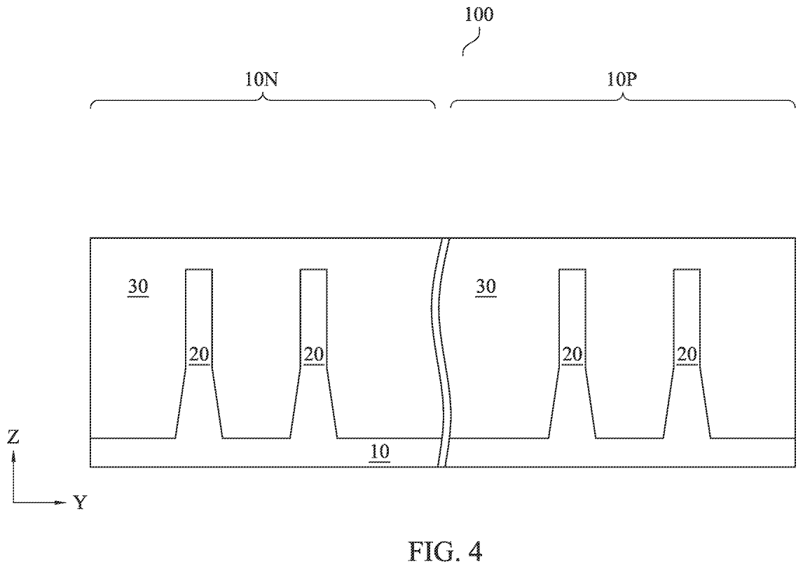

In FIG. 4, an insulation material 30 is formed over the substrate 10 and between neighboring fins 20. The insulation material 30 may be an oxide, such as silicon oxide, a nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In some embodiments, the insulation material 30 includes silicon oxide (such as SiO₂).

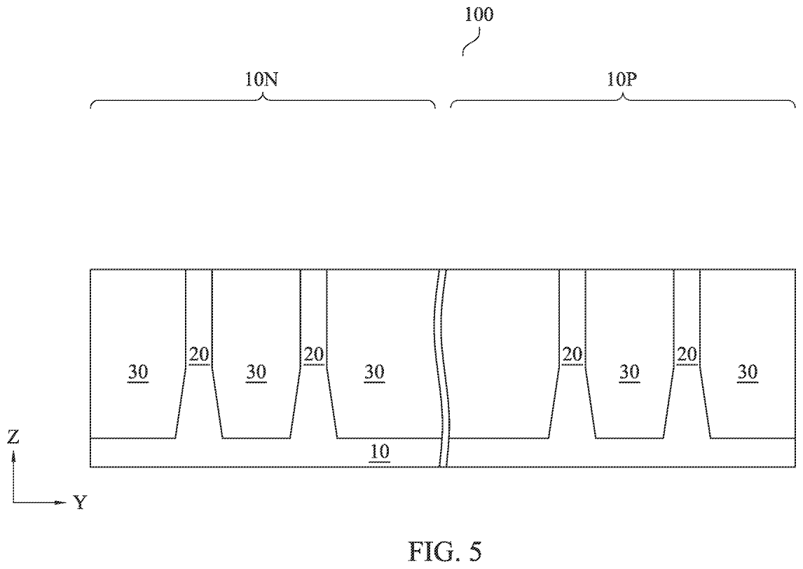

In FIG. 5, a planarization process is applied to the insulation material 30 to remove excess insulation material 30 over the fins 20. In some embodiments, a chemical mechanical polish (CMP), an etch-back process, combinations thereof, or the like is utilized. After the planarization process is complete, the fins 20 are exposed, and top surfaces of the fins 20 and the insulation material 30 are leveled.

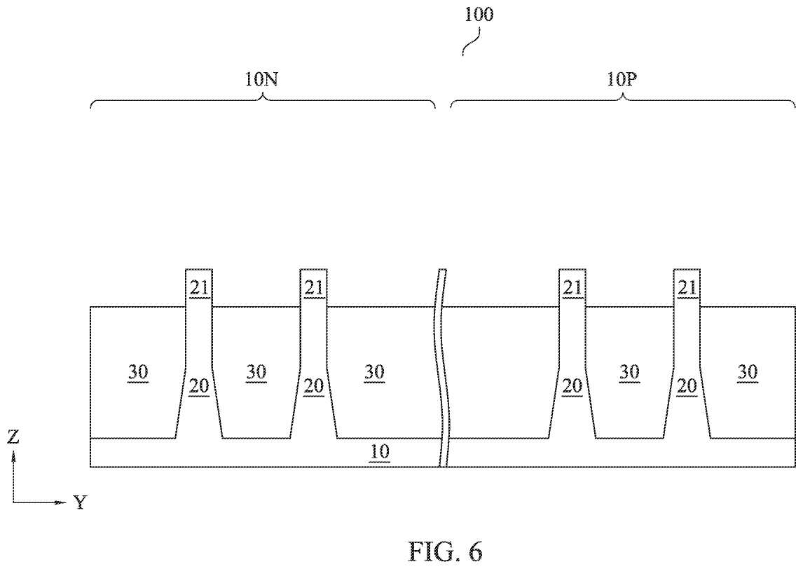

In FIG. 6, the insulation material 30 is recessed to form shallow trench isolation (STI) regions. In some embodiments, the insulation material 30 is recessed such that upper portions 21 (or channel regions 21) of the fins 20 protrude from neighboring STI regions 30. The top surfaces of the STI regions 30 is formed flat, convex, or concave by an appropriate etch. The STI regions 30 are recessed using one or more acceptable etching processes. In some embodiments, an etching rate of the insulation material 30 is faster than an etching rate of the material of the fins 20.

The processes described with respect to FIGS. 2 through 6 are just examples of how the fins 20 are formed. The fins 20 can be formed in other ways. Further, appropriate wells (not shown) may be formed in the fins 20 and/or the substrate 10. In some embodiments, a P well may be formed in the region 10N, and an N well may be formed in the region 10P. In some embodiments, a P well and an N well are formed in both regions 10N and 10P.

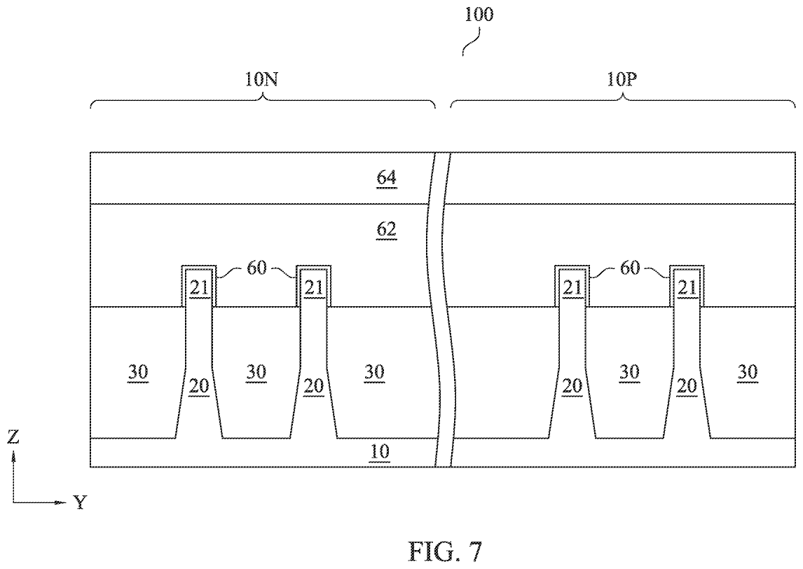

In FIG. 7, a dummy dielectric layer 60 is formed on the fins 20. The dummy dielectric layer 60 is e.g., silicon oxide, silicon nitride, a combination thereof, or the like, and may be deposited or thermally grown by acceptable techniques. A dummy gate layer 62 is formed over the dummy dielectric layer 60. The dummy gate layer 62 is then planarized by a CMP for example. The mask layer 64 is deposited over the dummy gate layer 62.

The dummy gate layer 62 is e.g., a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 62 is deposited by physical vapor deposition (PVD), CVD, sputter deposition, or other techniques known and used in the art.

The mask layer 64 includes e.g., silicon nitride, silicon oxynitride, or the like. In some embodiments, a dummy gate layer 62 and a mask layer 64 are formed across the region 10N and the region 10P. In some embodiments, the dummy dielectric layer 60 is deposited such that the dummy dielectric layer 60 covers the STI regions 30, extending between the dummy gate layer 62 and the STI regions 30.

In FIGS. 8A, 8B and 8C, the mask layer 64 is patterned using acceptable photolithography and etching techniques to form a mask 74. The pattern of the mask 74 is then transferred to the dummy gate layer 62 (also see FIG. 7). In some embodiments, the pattern of the mask 74 is transferred to the dummy dielectric layer 60 by an acceptable etching technique to form a dummy gate 72. The dummy gate 72 covers respective channel regions 21 of the fins 20.

As shown in FIG. 8B, in some embodiments, a dummy gate seal layer 80 is formed on exposed surfaces of the dummy gate 72, the mask 74, and/or the upper portion 21 of the fin 20. A thermal oxidation or a deposition followed by an anisotropic etch is used to form the dummy gate seal layer 80. The dummy gate seal layer 80 is made of silicon oxide, silicon nitride, silicon oxynitride, or the like.

As shown in FIG. 8C, in some embodiments, the dummy gate 72 has a flared profile (or a triangled profile) near the fins 20 in plan view. The flared profile may result, for example, from the topography of the sidewalls of the upper portion 21 of the fin 20, which affects the photolithography and/or etching steps forming the masks 74 or dummy gates 72. In some embodiments, regions of the dummy gates 72 away from the fins 20 have a width W1 that is in a range from about 6 nm to about 500 nm. In some embodiments, regions of the dummy gates 72 near the fins 20 have a width W2 that is greater than W1 and is in a range from about 16 nm to about 510 nm, and the width W2 is in a range from about 20 nm to about 400 nm in other embodiments. In some embodiments, the flared profile of the dummy gate 72 forms an angle θ1 with respect to the sidewall of the fin 20. The angle θ1 is in a range from about 5 degrees to about 80 degrees in some embodiments, and is in a range from about 20 degrees to about 70 degrees in other embodiments.

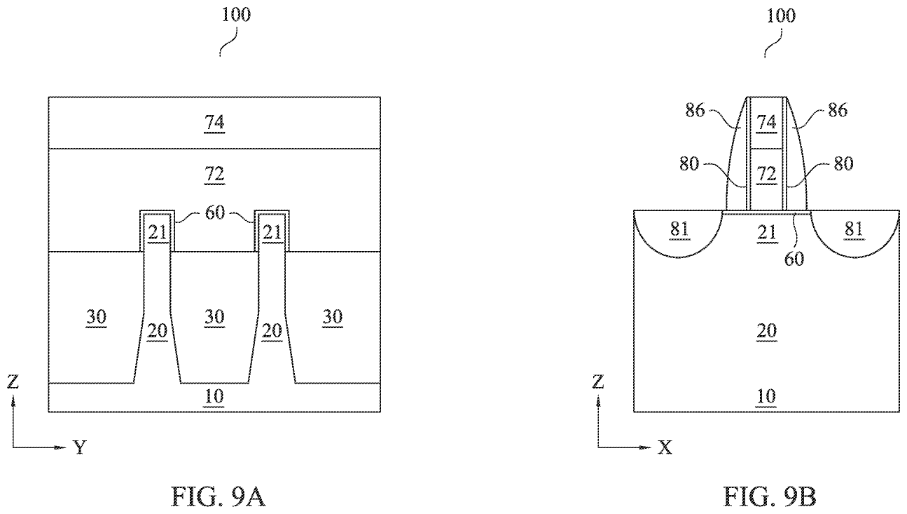

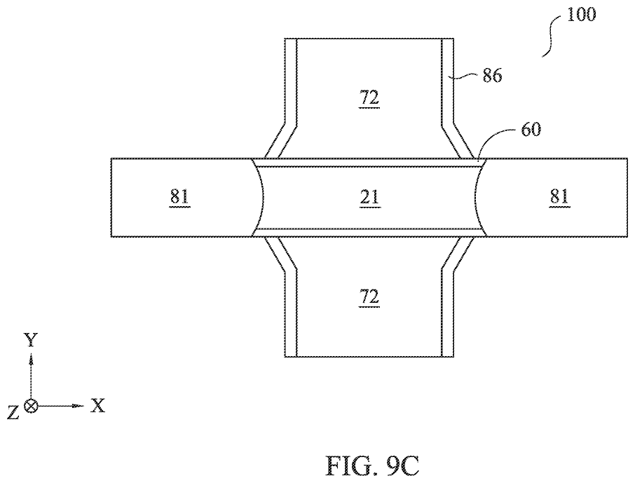

In FIGS. 9A, 9B and 9C, gate sidewall spacers 86 are formed on the gate seal spacers 80 along sidewalls of the dummy gate 72 and the mask 74. In some embodiments, the dummy gate spacers 86 are formed by conformally depositing an insulating material and subsequently anisotropically etching the insulating material. The gate sidewall spacers 86 include one or more layers of silicon oxide, silicon nitride, silicon oxynitride, silicon carbonitride, or the like.

After the formation of the dummy gate seal spacer 80, as shown in FIGS. 9B and 9C, the source/drain regions of the fin 20 are recessed or etched to form source/drain spaces 81 in some embodiments. The above disclosure describes a process of forming spacers and source/drain regions. Other suitable processes and sequences may be used. For example, fewer or additional spacers 86 may be utilized, and different sequences of steps may be utilized.

In FIGS. 10A, 10B, 10C, 10D, 10E and 10F, epitaxial source/drain regions 82 are formed in the source/drain spaces 81 (see FIGS. 9B an d9C) of the fins 20 to exert stress in the respective channel regions 21, thereby improving performance.

The epitaxial source/drain regions 82 in the region 10N, e.g., the NMOS region, may be formed by masking the region 10P, e.g., the PMOS region, and etching source/drain regions of the fins 20 in the region 10N to form recesses in the fins 20. The epitaxial source/drain regions 82 may include any acceptable material for n-type FinFETs. For example, if the fin 20 is silicon, the epitaxial source/drain regions 82 in the region 10N may include materials exerting a tensile strain in the channel region 21, such as silicon, silicon carbide, phosphorous doped silicon carbide, silicon phosphide, or the like. The epitaxial source/drain regions 82 in the region 10N may have surfaces raised from respective surfaces of the fins 20 and may have facets.

The epitaxial source/drain regions 82 in the region 10P, e.g., the PMOS region, may be formed by masking the region 10N, e.g., the NMOS region, and etching source/drain regions of the fins 20 in the region 10P to form recesses in the fins 20. The epitaxial source/drain regions 82 may include any acceptable material appropriate for p-type FinFETs. For example, if the fin 20 is silicon, the epitaxial source/drain regions 82 in the region 10P may include materials exerting a compressive strain in the channel region 21, such as silicon-germanium, boron doped silicon-germanium, germanium, germanium tin, or the like. The epitaxial source/drain regions 82 in the region 10P may also have surfaces raised from respective surfaces of the fins 20 and may have facets.

FIGS. 10D and 10E are cross sectional views along cross section line C-C illustrated in FIG. 10F. In some embodiments, these facets in the regions 10N and 10P cause adjacent source/drain regions 82 of a same FinFET to merge as illustrated by FIG. 10D. In other embodiments, adjacent source/drain regions 82 remain separated after the epitaxy process is completed as illustrated by FIG. 10E. As shown in FIGS. 10D and 10E, the gate sidewall spacers 86 are also formed covering portions of the sidewalls of the upper portions 21 of the fins 20 that extend above the STI regions 30, which block or constrain the epitaxial growth.

In FIGS. 11A and 11B, a first interlayer dielectric (ILD) 88 is deposited over the structure illustrated in FIGS. 10A and 10B. The first ILD 88 is formed of a dielectric material, and may be deposited by any suitable method, such as CVD, plasma-enhanced CVD (PECVD), or FCVD. Dielectric materials include e.g., phospho-silicate glass (PSG), boro-silicate glass (BSG), boron-doped phospho-silicate glass (BPSG), undoped silicate glass (USG), or the like. Other insulation materials formed by any acceptable process can also be used.

In some embodiments, a contact etch stop layer (CESL) 87 is disposed between the first ILD 88 and the epitaxial source/drain regions 82, the masks 74, and the dummy gate spacers 86. In some embodiments, the CESL 87 includes a dielectric material, such as, silicon nitride, silicon oxide, silicon oxynitride, or the like, has a different etch rate than the material of the overlying first ILD 88.

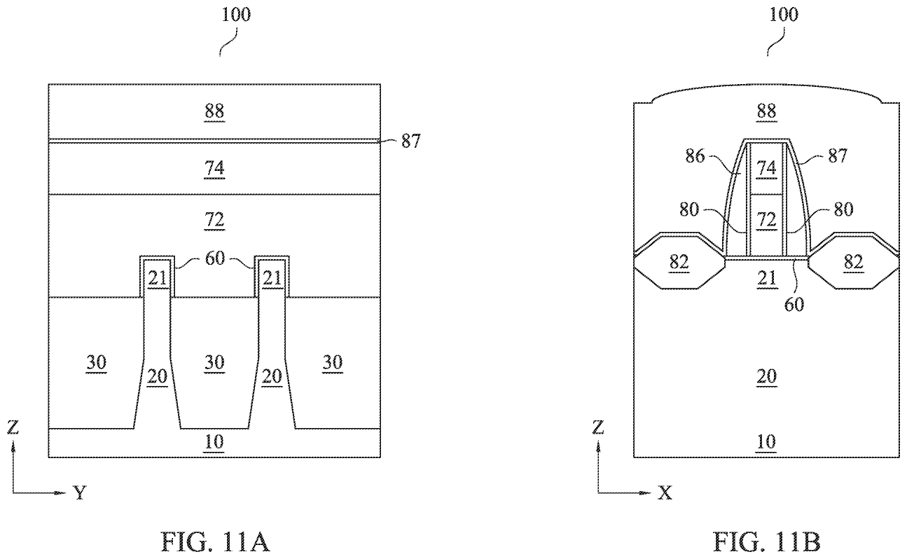

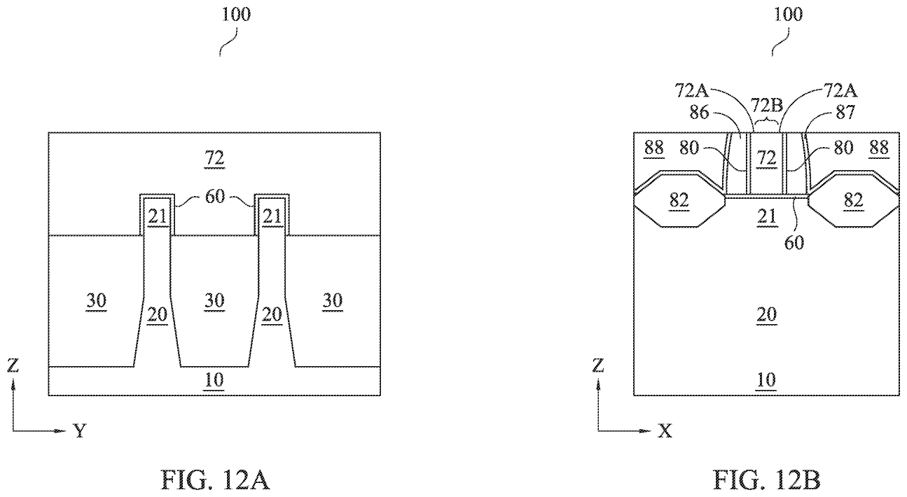

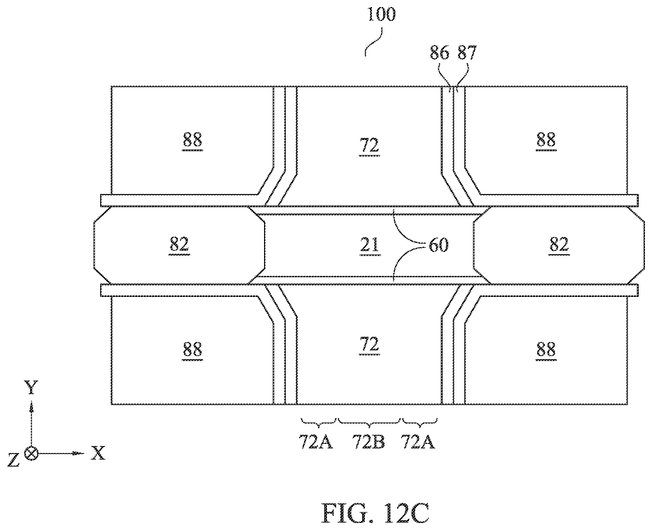

In some embodiments, as shown in FIGS. 12A, 12B, and 12C, a planarization process (such as a CMP) is performed to level top surfaces of the first ILD 88, the dummy gate 72, and the mask 74. After the planarization process, the top surfaces of the dummy gate 72, the gate seal spacers 80, the dummy gate spacers 86, and the first ILD 88 are leveled. Accordingly, the top surface of the dummy gate 72 is exposed through the first ILD 88.

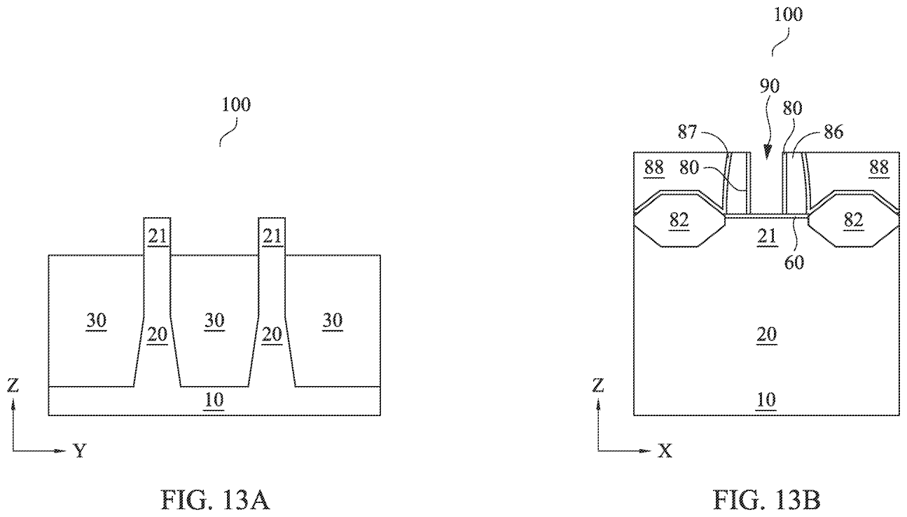

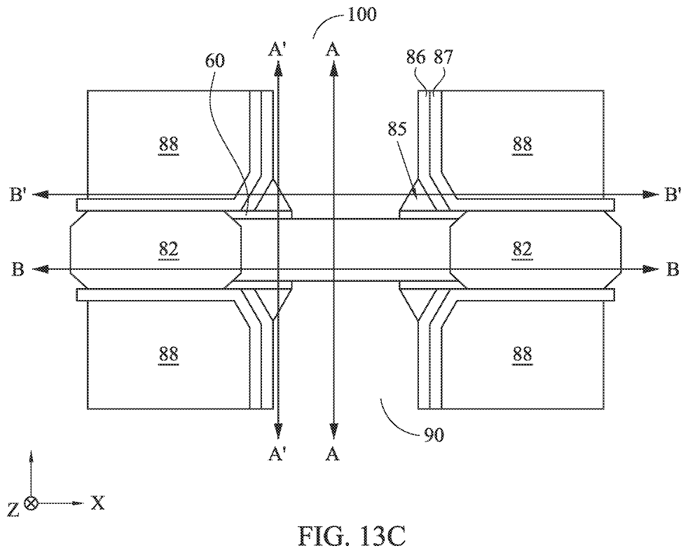

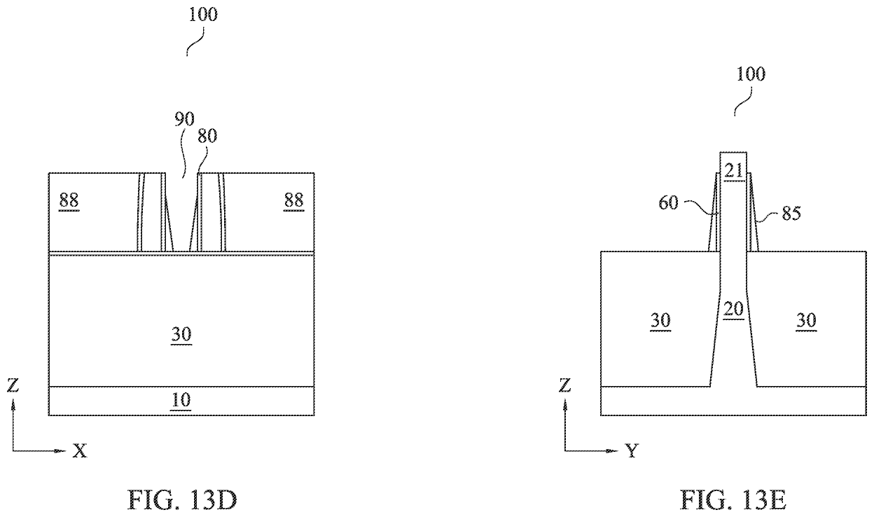

FIG. 13A is a cross sectional view along cross section line A-A illustrated in FIG. 13C. FIG. 13B is a cross sectional view along cross section line B-B illustrated in FIG. 13C. FIG. 13D is a cross sectional view along cross section line B′-B′ illustrated in FIG. 13C. FIG. 13E is a cross sectional view along cross section line A′-A′ illustrated in FIG. 13C. In FIGS. 13A and 13B, portions of the dummy gates 72 and the gate dielectric layer 60 (also see FIGS. 12A, 12B and 12C) are removed in etching steps so that recesses 90 are formed in the dummy gate 72 and the top surface of the channels 21 of the fins 20 are exposed in some embodiments. In other embodiments, the dummy gate structure 72 has a taper shaped profile having an upper width less than a lower width, and an anisotropic dry etching process is used to remove portions of the dummy gate 72. In some embodiments, the anisotropic dry etching process includes a plasma etching process.

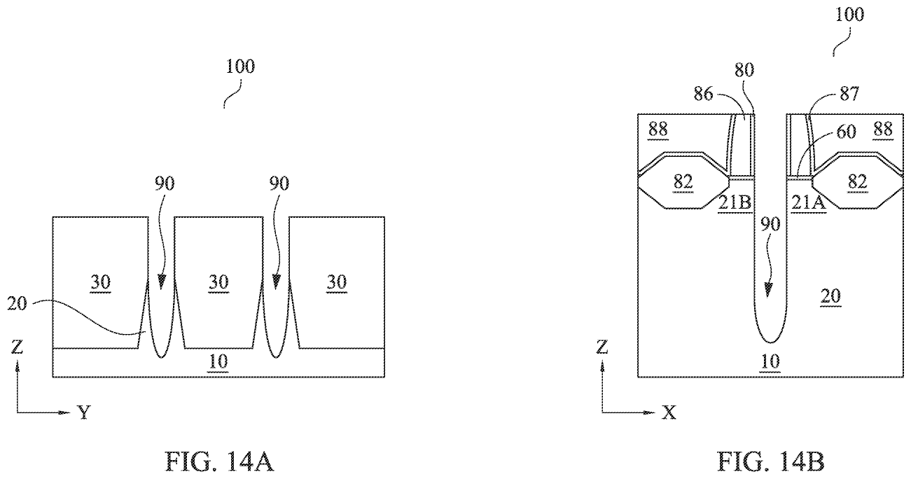

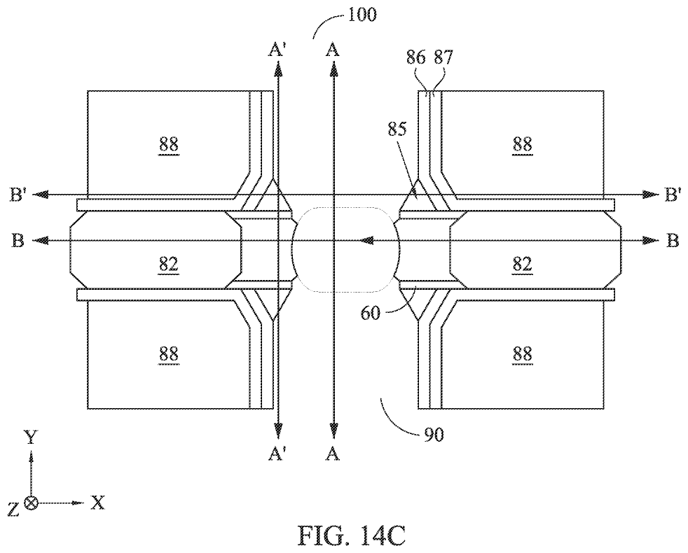

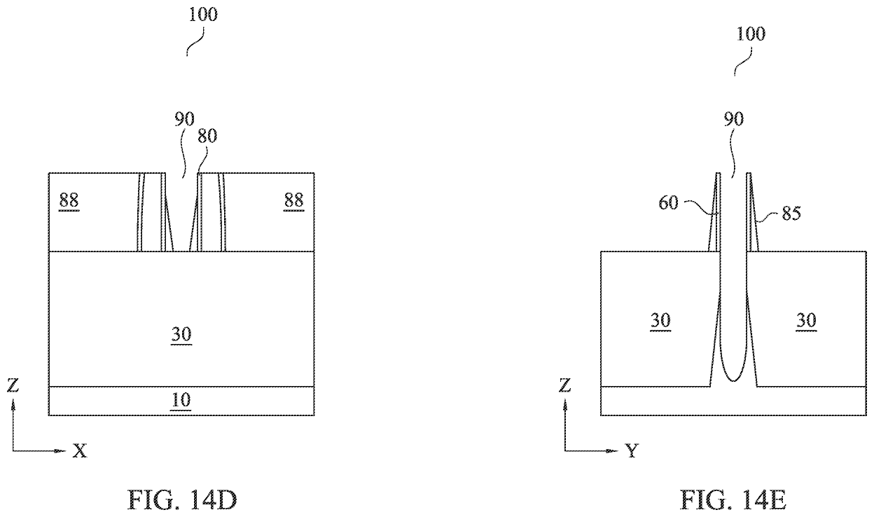

FIG. 14A is a cross sectional view along cross section line A-A illustrated in FIG. 14C. FIG. 14B is a cross sectional view along cross section line B-B illustrated in FIG. 14C. FIG. 14D is a cross sectional view along cross section line B′-B′ illustrated in FIG. 14C. FIG. 14E is a cross sectional view along cross section line A′-A′ illustrated in FIG. 14C. In FIGS. 14A and 14B, a further etching process is performed on the exposed top surfaces of the fins 20 to further remove at least portions of the channels 21 of the fins 20 previously underlying the dummy gate structure 72. The recesses 90 thus further extend into the substrate 10, cut the channels 21 of the fins 20, and forms two fin ends 21A and 21B that are separated from each other. In some embodiments, the recess 90 formed in the dummy gate structure 72 has a round-cornered rectangular shape (or a stadium like shape).

In some embodiments, after performing the etching process, the top surface of the fin end 21A of the channel region 21 protrudes from the spacer layer 86 into the recess 90 along a fin extending direction in plan view, and portions 85 of the dummy gate structure 72 remain in corner regions that are defined by the spacer layer 86 and the top surface of the fin end 21A of the channel region 21. In some embodiments, the remaining portions 85 of the dummy gate structure 72 have a triangle shape or a flared shape.

The remaining portions 85 of the dummy gate structure 72 can be formed in different ways. Referring to FIGS. 12B and 12C, the dummy gate 72 includes first portions 72A relatively close to the spacer layers 86 and second portions 72B of the dummy gate 72 relatively far away from the spacer layers 86, and the second portions 72B are adjacent the first portions 72A.

In some embodiments, the first portions 72A and the second portions 72B of the dummy gate 72 are simultaneously etched respectively at a first and a second etching rates. The second etching rate of the second portions 72B is faster than the first etching rate of the first portions 72A. The etching process stops after the second portions 72B of the dummy gate 72 (and at least a portion of the gate dielectric layer 60) are removed, and thus the first portions 72A of the dummy gate 72 remain after stopping the etching process. In this way, the remaining portions 85 of the dummy gate 72 are formed in corner regions defined between the spacers 86 and the fin ends (such as 21A and 21B).

In other embodiments, the dummy gate structure 72 has a taper shaped profile having an upper width less than a lower width, and an anisotropic dry etching process is used to remove portions of the dummy gate 72. In some embodiments, the anisotropic dry etching process includes a plasma etching process. Thus, remaining portions 85 of the dummy gate 72 are formed in corner regions defined between the spacers 86 and the fin ends (such as 21A and 21B).

In some embodiments, during the removal process, the dummy dielectric layer 60 is used as an etch stop layer when the dummy gates 72 are etched. The dummy dielectric layer 60 is then optionally removed after the removal of the dummy gates 72.

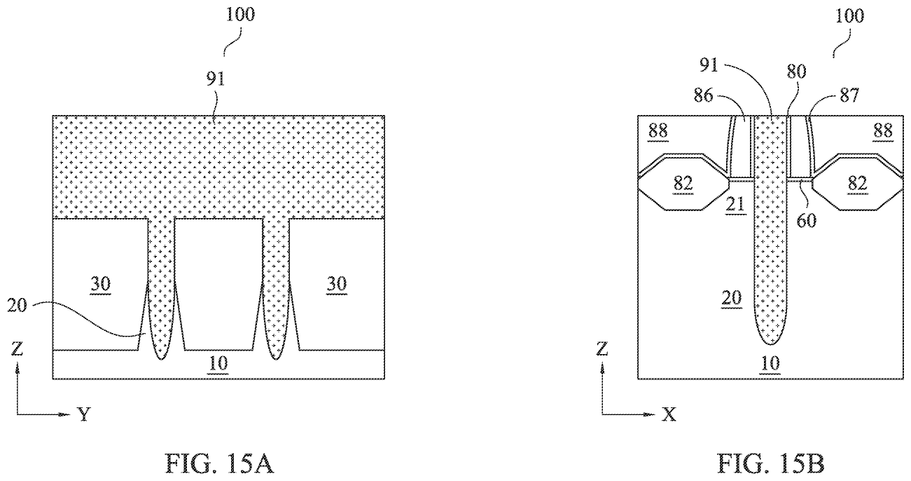

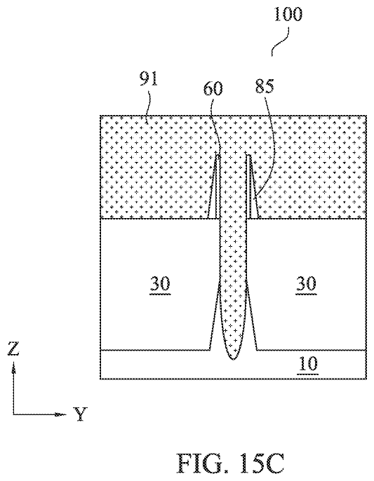

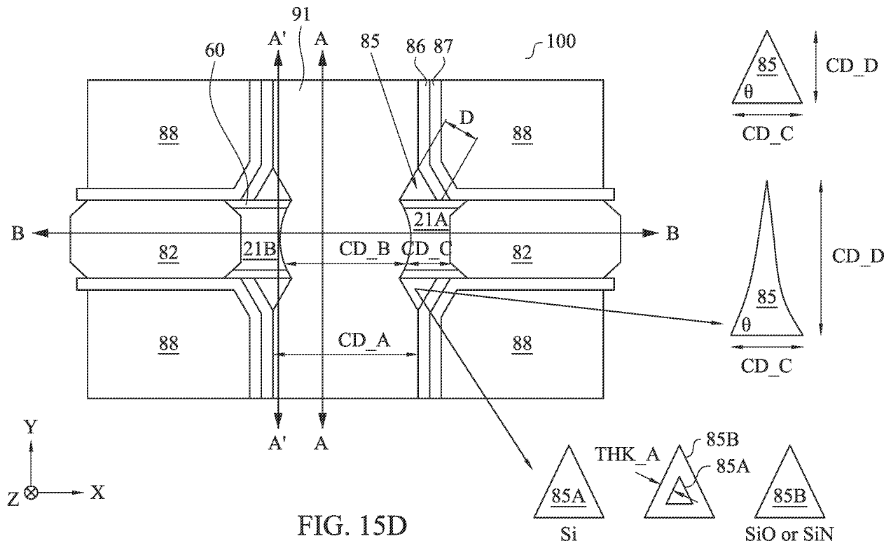

In FIGS. 15A, 15B, 15C and 15D, a separation structure 91 is formed in the recess 90 to separate adjacent fin ends 21A and 21B in some embodiments. FIG. 15D is a top view of the semiconductor 100 including the separation structure 91. FIG. 15A is a cross sectional view illustrated along cross section line A-A shown in FIG. 15D. FIG. 15B is a cross sectional view illustrated along cross section line B-B shown in FIG. 15D. FIG. 15C is a cross sectional view illustrated along cross section line A′-A′ shown in FIG. 15D.

In some embodiments, the separation structure 91 is formed by depositing one or more dielectric materials in the recess 90 and planarizing the deposited dielectric materials by, for example, CMP. In some embodiments, the separation structure 91 is made of a dielectric material, which is selected from silicon oxide, silicon nitride, the combination thereof, or the like. In some embodiments, the dielectric material of the separation structure 91 includes SiN, SiON, SiOCN, SiC, SiOC, SiCN, SiO2, SiC, HfO, etc.

In some embodiments, as shown in FIG. 15D, the remaining portions 85 of the dummy gate structure 72 protrude from the dummy gate spacers 86 into the separation structure 91 with a distance (CD_C), which is in a range from about 1 nm to about 100 nm. The remaining portions 85 of the dummy gate structure 72 further separate portions of the separation structure 91 from the source/drain region 82, and thus advantageously prevent the source/drain region 82 from being in risks or damaged during the fabricating and/or the processing of the recess 90 and/or the separation structure 91.

In some embodiments, as shown in FIG. 15D, a semiconductor device 100 includes a fin 21 extending from a substrate 10 (also see FIGS. 15A, 15B and 15C) and including a fin end 21A, a separation structure 91 separating the fin end 21A from an adjacent fin end 21B, a spacer 86 along a first sidewall of the separation structure 91 and a sidewall of the fin 21, a first epitaxial source/drain region 82 in the fin 21 and adjacent the fin end, and a residue 85 of a dummy gate material in a corner region between the spacer 86 and the fin end 21A. The fin end 21A protrudes from the spacer 86 into the separation structure 91. The residue 85 is triangle shaped and disposed between the first epitaxial source/drain region 82 and the separation structure 91. In some embodiments, the residue 85 of the dummy gate material includes silicon, silicon oxide, silicon nitride, or a combination thereof. The presence of the remaining portions 85 of the dummy gate material 72 increases the distance “D” from the epitaxial source/drain regions 82 to the separation structure 91 (as shown in FIG. 15D), and thus increases the process distance window, accordingly reducing the risk of damaging the epitaxial source/drain regions during the process of forming the separation structure.

In some embodiments, as shown in FIGS. 15B and 15D, the separation structure 91 includes a dielectric plug 91 that extends along the first sidewall into the substrate 10 and separates the fin end 21A of the fin 21 from an adjacent fin end 21B of another fin 21.

In some embodiments, as shown in FIGS. 15B and 15D, the semiconductor device 100 further includes a dummy dielectric layer 60 on the sidewall of the fin 21, a dummy gate seal layer 80 between the separation structure 91 and the spacer 86, and a CESL 87 on the spacer 86.

In some embodiments, as shown in FIG. 15D, a side of the residue 85 adjacent the separation structure 91 forms a first angle θ with respect to the sidewall of the fin 21 in plan view. The first angle θ is in a range from about 5° to about 80° in some embodiments, and is in a range from 20° to 60° in other embodiments.

In some embodiments, as shown in FIG. 15D, a base width CD_C of the triangle shaped residue 85 is in a range from about 1 nm to about 100 nm, and is in a range from about 20 nm to about 80 nm in other embodiments. In some embodiments, a height CD_D of the triangle shaped residue 85 is in a range from about 1 nm to about 100 nm, and is in a range from about 20 nm to about 80 nm in other embodiments.

In some embodiments, as shown in FIG. 15D, a ratio of a width CD_A of the separation structure 91 to the base width CD_C of the triangle shaped residue 85 is in a range from about 0.03 to about 600, and is in a range from about 10 to about 400 in other embodiments.

In some embodiments, as shown in FIG. 15D, a ratio of a distance CD_B between of the fin end 21A of the fin 21 and the adjacent fin end 21B of another fin 21 to the base width CD_C of the triangle shaped residue 85 is in a range from about 0.03 to about 600, and is in a range from about 10 to about 400 in other embodiments.

When the base width, the ratio of the width to base width, or the ratio of the distance between the end fins and the base width are less than the disclosed ranges, there may be an insufficient increase in the process window to prevent the risk of damaging the epitaxial source/drain regions during fabricating and processing the separation structure, and when these values are greater than the disclosed ranges, there may be a decrease in device performance.

In some embodiments, as shown in FIG. 15D, the triangle shaped residue 85 includes a first triangle shaped residue 85A and a second triangle shaped residue 85B enclosing the first triangle shaped residue 85A. In some embodiments, the first residue 85A includes Si and the second residue 85B includes silicon oxide (such as SiO) or silicon nitride (such as SiN). In some embodiments, as shown in FIG. 15D, distance (THK_A) between corresponding parallel sides of the first triangle shaped residue (85A) and the second triangle shaped residue (85B) is in a range from about 0.5 nm to about 10 nm.

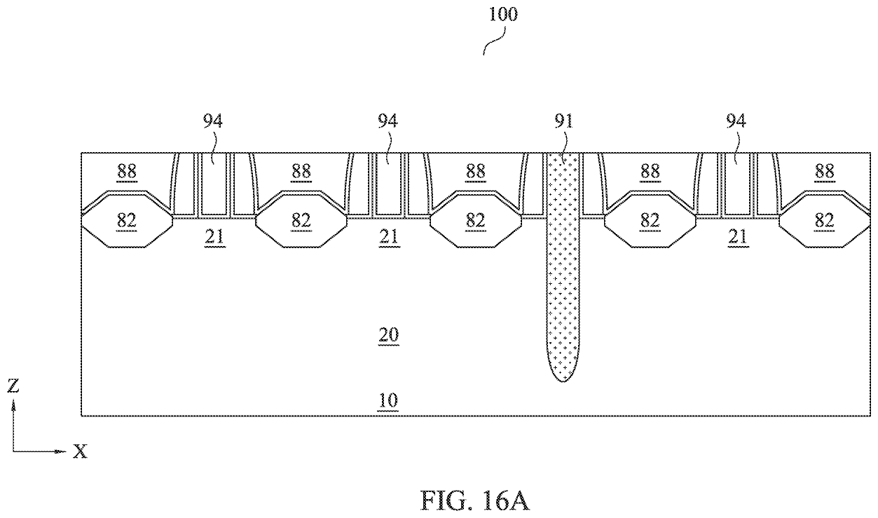

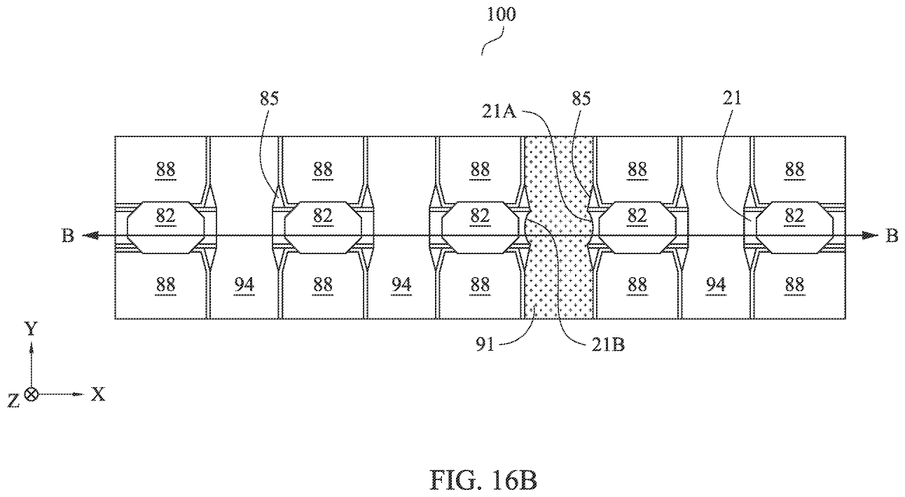

In FIGS. 16A and 16B, a separation structure 91 (fabricated from a dummy gate 72) and several active gate structures 94 are illustrated. FIG. 16A is a cross sectional view along cross section line B-B shown in FIGS. 1 and 16B. As shown in FIG. 16B, the remaining portions 85 of the dummy gate structure 72 protrude from the dummy gate spacers 86 into the separation structure 91 and further separate portions of the separation structure 91 from the source/drain region 82. Each of the active gate structures 94 also includes remaining portions 85 of the dummy gate structure 72 that separates the active gate structure 94 from the source/drain region 82. In some embodiments, one or more active gate structures 94 are formed, and each active gate structure 94 is formed between a pair of source/drain regions 82.

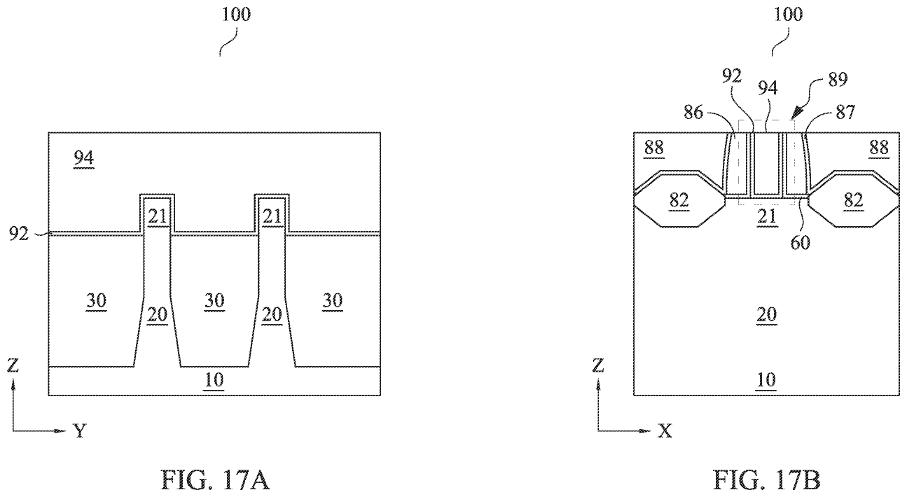

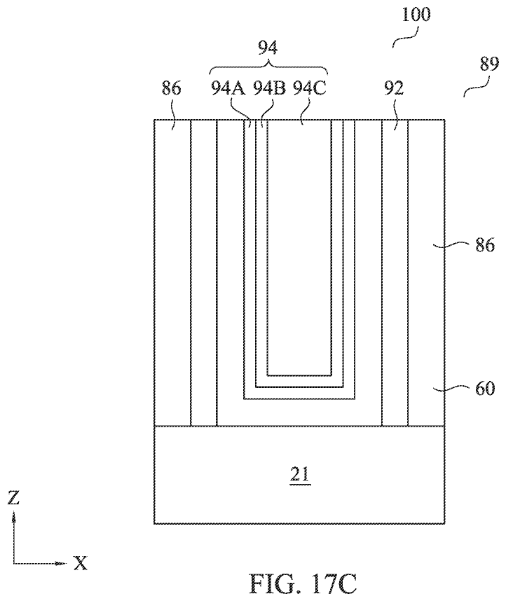

In FIGS. 17A, 17B and 17C, gate dielectric layers 92 and gate electrodes 94 are formed for active gates in accordance with some embodiments. FIG. 17C illustrates a detailed view of region 89 of FIG. 17B. Gate dielectric layers 92 are deposited conformally in the recesses 90, such as on the top surfaces and the sidewalls of the fins 20 and on sidewalls of the gate seal spacers 80 and/or gate spacers 86. The gate dielectric layers 92 may also be formed on the top surface of the first ILD 88. In accordance with some embodiments, the gate dielectric layers 92 include silicon oxide, silicon nitride, or multilayers thereof. In some embodiments, the gate dielectric layers 92 include a high-k dielectric material, and in these embodiments, the gate dielectric layers 92 may have a k value greater than about 7.0, and may include a metal oxide or a silicate of hafnium, aluminum, zirconium, lanthanum, manganese, barium, titanium, lead, and combinations thereof.

The gate electrodes 94 are deposited over the gate dielectric layers 92, respectively, and fill the remaining portions of the recesses 90. The gate electrodes 94 may include a metal-containing material such as titanium nitride, titanium oxide, tantalum nitride, tantalum carbide, cobalt, ruthenium, aluminum, tungsten, combinations thereof, or multi-layers thereof. After the filling of the recesses 90, a planarization process, such as a CMP, may be performed to remove the excess portions of the gate dielectric layers 92 and the material of the gate electrodes 94 that are over the top surface of the ILD 88.

The formation of the gate dielectric layers 92 in the region 10N and the region 10P may occur simultaneously such that the gate dielectric layers 92 in each region are formed from the same materials, and the formation of the gate electrodes 94 may occur simultaneously such that the gate electrodes 94 in each region are formed from the same materials. In some embodiments, the gate dielectric layers 92 in each region are formed by distinct processes, such that the gate dielectric layers 92 include different materials, and/or the gate electrodes 94 in each region are formed by distinct processes, such that the gate electrodes 94 include different materials. Various masking steps may be used to mask and expose appropriate regions when using distinct processes.

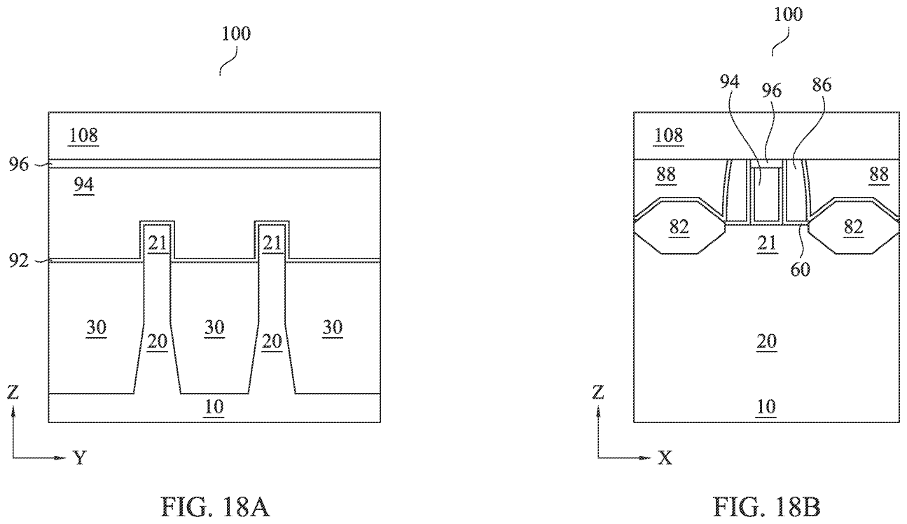

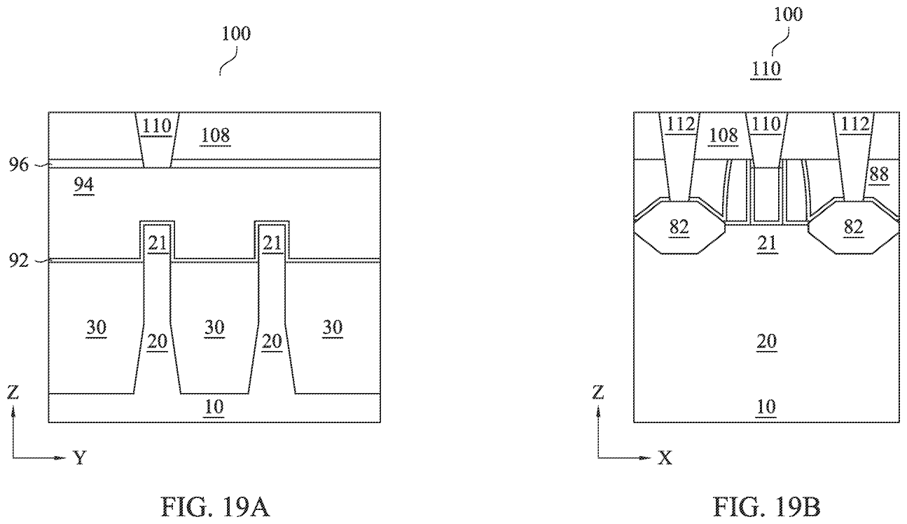

In FIGS. 18A and 18B, a second ILD 108 is deposited over the first ILD 88. In some embodiments, the second ILD 108 is a flowable film formed by a flowable CVD method. In some embodiments, the second ILD 108 is formed of a dielectric material such as PSG, BSG, BPSG, USG, or the like, and may be deposited by any suitable method, such as CVD and PECVD. In accordance with some embodiments, before the formation of the second ILD 108, the gate stack (including a gate dielectric layer 92 and a corresponding overlying gate electrode 94) is recessed, so that a recess is formed directly over the gate stack and between opposing portions of gate spacers 86, as illustrated in FIGS. 18A and 18B. A gate mask 96 including one or more layers of dielectric material, such as silicon nitride, silicon oxynitride, or the like, is filled in the recess, followed by a planarization process to remove excess portions of the dielectric material extending over the first ILD 88. The subsequently formed gate contacts 110 (FIGS. 19A and 19B) penetrate through the gate mask 96 to contact the top surface of the recessed gate electrode 94.

In FIGS. 19A and 19B, gate contacts 110 and source/drain contacts 112 are formed through the second ILD 108 and the first ILD 88 in accordance with some embodiments. Openings for the source/drain contacts 112 are formed through the first ILD 88 and the second ILD 108, and openings for the gate contact 110 are formed through the second ILD 108 and the gate mask 96. The openings may be formed using acceptable photolithography and etching techniques. A liner, such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like.

A planarization process, such as a CMP, is performed to remove excess material from a surface of the ILD 108. The remaining liner and conductive material form the source/drain contacts 112 and gate contacts 110 in the openings. An anneal process is performed to form a silicide at the interface between the epitaxial source/drain regions 82 and the source/drain contacts 112. The source/drain contacts 112 are physically and electrically coupled to the epitaxial source/drain regions 82, and the gate contacts 110 are physically and electrically coupled to the gate electrodes 94. The source/drain contacts 112 and gate contacts 110 may be formed in different processes, or may be formed in the same process.

According to embodiments of the present disclosure, a semiconductor device includes a fin extending from a semiconductor substrate and including a fin end, a separation structure separating the fin end from an adjacent fin end, a spacer along a first sidewall of the separation structure and a sidewall of the fin, a first epitaxial source/drain region in the fin and adjacent the separation structure, and a residue of a dummy gate material in a corner region between the spacer and the fin end. The fin end protrudes from the spacer into the separation structure, and the residue of the dummy gate material separates the first epitaxial source/drain region from the separation structure.

Additionally, a method of forming a semiconductor device includes forming a fin including a channel region, forming a dummy gate structure extending over the channel region, forming a spacer on sidewalls of the dummy gate structure and the channel region, epitaxially growing a source/drain region adjacent the channel region, performing an etching process on the dummy gate structure to form a recess in and through the dummy gate structure and to cut the channel region, and forming a separation structure in the recess. After performing the etching process, a fin end of the channel region is formed and protrudes beyond the spacer into the recess, and portions of the dummy gate structure remain in corner regions defined by the spacer and the fin cut end of the channel region.

The presence of the remaining portions of the dummy gate material increases the distance from the epitaxial source/drain regions to the separation structure, and further separates portions of the separation material from the source/drain region. The remaining portions of the dummy gate material thus advantageously increases the available process window, reduces the risk of damaging the epitaxial source/drain regions during fabricating and processing the separation structure, thereby enhancing yield, and improving performance of the semiconductor device.

In accordance with an aspect of the present disclosure, a semiconductor device includes a fin extending from a substrate and including a fin end; a separation structure separating the fin end from an adjacent fin end of another fin; a spacer along a first sidewall of the separation structure and a sidewall of the fin; a first epitaxial source/drain region in the fin and adjacent the fin end; and residue of a dummy gate material in a corner region between the spacer and the fin end. The fin end protrudes from the spacer into the separation structure. The residue is tangle shaped, and is disposed between the first epitaxial source/drain region and the separation structure. In one or more of the foregoing and/or following embodiments, the separation structure includes a dielectric plug extending along the first sidewall into the substrate and separates the fin end from the adjacent fin end of the another fin. In one or more of the foregoing and/or following embodiments, the residue of the dummy gate material includes silicon, silicon oxide, silicon nitride, or a combination thereof. In one or more of the foregoing and/or following embodiments, a side of the residue adjacent the separation structure forms a first angle with respect to the sidewall of the fin in plan view in a range from 5° to 80°. In one or more of the foregoing and/or following embodiments, a base width of the triangle shaped residue is in a range from 1 nm to 100 nm, and wherein a height of the triangle shaped residue is in a range from 1 nm to 100 nm. In one or more of the foregoing and/or following embodiments, a ratio of a width of the separation structure to a base width of the triangle shaped residue is in a range from 0.03 to 600. In one or more of the foregoing and/or following embodiments, a ratio of a distance between of the fin end and the adjacent fin end of the another fin to a base width of the triangle shaped residue is in a range from 0.03 to 600. In one or more of the foregoing and/or following embodiments, the triangle shaped residue includes a first triangle shaped residue and a second triangle shaped residue enclosing the first triangle shaped residue, and the first residue includes Si and the second residue includes silicon oxide or silicon nitride. In one or more of the foregoing and/or following embodiments, a distance between corresponding parallel sides of the first triangle shaped residue and the second triangle shaped residue is in a range from 0.5 nm to 10 nm. In one or more of the foregoing and/or following embodiments, the semiconductor device further includes a dummy dielectric layer on the sidewall of the fin, a dummy gate seal layer between the separation structure and the spacer, and a contact etch stop layer (CESL) on the spacer.

In accordance with an aspect of the present disclosure, a method of forming a semiconductor device includes forming a fin on a substrate; forming a first isolation region surrounding the fin, an upper region of the fin protruding above the first isolation region and forming a channel region; forming a dummy gate structure extending over the first isolation region and the upper region; forming a spacer on sidewalls of the dummy gate structure and the upper region; epitaxially growing a source/drain region adjacent the upper region; performing an etching process on the dummy gate structure to form a recess in and through the dummy gate structure and to remove the upper region underlying the dummy gate structure; and forming a separation structure in the recess. After performing the etching process, a fin end of the upper region is formed and protrudes from the spacer into the recess along a fin extending direction in plan view, and portions of the dummy gate structure remain in corner regions defined by the spacer and the fin cut end of the upper region. The remaining portions of the dummy gate structure separate portions of the separation structure from the source/drain region. In one or more of the foregoing and/or following embodiments, the remaining portions of the dummy gate structure have a triangle shape. In one or more of the foregoing and/or following embodiments, the etching process includes an anisotropic dry etching process, and the anisotropic dry etching process includes a plasma etching process. In one or more of the foregoing and/or following embodiments, the recess formed in the dummy gate structure has a round-cornered rectangular shape in plan view. In one or more of the foregoing and/or following embodiments, forming the separation structure includes forming a dielectric plug into the substrate, the dielectric plug separating the fin end of the fin from an adjacent fin end of another fin.

In accordance with an aspect of the present disclosure, a method of forming a semiconductor device includes forming a fin protruding from a semiconductor substrate; forming a dummy gate over the fin; forming dummy gate spacers on sidewalls of the dummy gate; performing an etching process on the dummy gate to form a recess; and forming a separation structure in the recess. The etching process includes: simultaneously etching first portions of the dummy gate at a first etching rate and etching second portions of the dummy gate at a second etching rate that is greater than the first etching rate, wherein each first portion of the dummy gate includes a first surface over a sidewall of a gate spacer and a second surface over a sidewall of the fin, wherein the second portions of the dummy gate are adjacent the first portions; and stopping the etching process after the second portions of the dummy gate and at least a portion of the fin under the second portions of the dummy gate are removed, wherein the first portions of the dummy gate remain after stopping the etching process. The remaining first portions of the dummy gate structure separate portions of the separation structure from the source/drain region, and wherein the remaining portions protrude from the dummy gate spacers into the separation structure with a distance in plan view in a range from 1 nm to 100 nm. In one or more of the foregoing and/or following embodiments, the method of forming a semiconductor device further includes forming a dummy gate dielectric over the fin. In one or more of the foregoing and/or following embodiments, the remaining portions of the dummy gate material include silicon, silicon oxide, silicon nitride, or a combination thereof. In one or more of the foregoing and/or following embodiments, the remaining portions of the dummy gate structure are triangle shaped. In one or more of the foregoing and/or following embodiments, a ratio of a width of the separation structure to a base width of a triangle shaped remaining portion of the dummy gate structure is in a range from 0.03 to 600.

It will be understood that not all advantages have been necessarily discussed herein, no particular advantage is required for all embodiments or examples, and other embodiments or examples may offer different advantages.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed:

1. A semiconductor device comprising:
a fin extending from a substrate and including a fin end;
a separation structure separating the fin end from an adjacent fin end of another fin;
a spacer along a first sidewall of the separation structure and a sidewall of the fin, wherein the fin end protrudes from the spacer into the separation structure;
a first epitaxial source/drain region in the fin and adjacent the fin end; and
a residue of a dummy gate material in a corner region between the spacer and the fin end, the residue being disposed between the first epitaxial source/drain region and the separation structure.

2. The semiconductor device of claim 1, wherein the separation structure comprises a dielectric plug extending along the first sidewall into the substrate and separating the fin end from the adjacent fin end of the another fin.

3. The semiconductor device of claim 1, wherein the residue of the dummy gate material comprises silicon, silicon oxide, silicon nitride, or a combination thereof.

4. The semiconductor device of claim 1, wherein a side of the residue adjacent the separation structure forms a first angle (θ) with respect to the sidewall of the fin in plan view in a range from 5° to 80°.

5. The semiconductor device of claim 1, wherein the residue is triangle shaped, and wherein a base width of the triangle shaped residue is in a range from 1 nm to 100 nm, and wherein a height of the triangle shaped residue is in a range from 1 nm to 100 nm.

6. The semiconductor device of claim 1, wherein the residue is triangle shaped, and wherein a ratio of a width of the separation structure to a base width of the triangle shaped residue is in a range from 0.03 to 600.

7. The semiconductor device of claim 1, wherein the residue is triangle shaped, and wherein a ratio of a distance between the fin end and the adjacent fin end of the another fin to a base width of the triangle shaped residue is in a range from 0.03 to 600.

8. The semiconductor device of claim 1, wherein the residue is triangle shaped, and wherein the triangle shaped residue comprises a first triangle shaped residue and a second triangle shaped residue enclosing the first triangle shaped residue, and wherein the first residue comprises Si and the second residue comprises silicon oxide or silicon nitride.

9. The semiconductor device of claim 8, wherein a distance between corresponding parallel sides of the first triangle shaped residue and the second triangle shaped residue is in a range from 0.5 nm to 10 nm.

10. The semiconductor device of claim 1, further comprising a dummy dielectric layer on the sidewall of the fin, a dummy gate seal layer between the separation structure and the spacer, and a contact etch stop layer (CESL) on the spacer.

11. A method of forming a semiconductor device, the method comprising:
forming a fin on a substrate;
forming a first isolation region surrounding the fin, wherein an upper region of the fin protrudes above the first isolation region and forms a channel region;
forming a dummy gate structure extending over the first isolation region and the upper region;
forming a spacer on sidewalls of the dummy gate structure and the upper region;
epitaxially growing a source/drain region adjacent the upper region;
performing an etching process on the dummy gate structure to form a recess in and through the dummy gate structure and to remove the upper region underlying the dummy gate structure, wherein after performing the etching process, a fin end of the upper region is formed and protrudes from the spacer into the recess along a fin extending direction in plan view, and portions of the dummy gate structure remain in corner regions defined by the spacer and the fin end of the upper region; and
forming a separation structure in the recess, wherein the remaining portions of the dummy gate structure separate portions of the separation structure from the source/drain region.

12. The method of claim 9, wherein the remaining portions of the dummy gate structure are triangle shaped.

13. The method of claim 9, wherein the etching process comprises an anisotropic dry etching process, and wherein the anisotropic dry etching process comprises a plasma etching process.

14. The method of claim 9, wherein the recess formed in the dummy gate structure has a round-cornered rectangular shape in plan view.

15. The method of claim 9, wherein forming the separation structure comprises forming a dielectric plug into the substrate, the dielectric plug separating the fin end of the fin from an adjacent fin end of another fin.

16. A method of forming a semiconductor device, the method comprising:
forming a fin protruding from a semiconductor substrate;
forming a dummy gate over the fin;
forming dummy gate spacers on sidewalls of the dummy gate;
performing an etching process on the dummy gate to form a recess, wherein the etching process comprises:
simultaneously etching first portions of the dummy gate at a first etching rate and etching second portions of the dummy gate at a second etching rate that is greater than the first etching rate, wherein each first portion of the dummy gate comprises a first surface over a sidewall of a gate spacer and a second surface over a sidewall of the fin, wherein the second portions of the dummy gate are adjacent the first portions; and
stopping the etching process after the second portions of the dummy gate and at least a portion of the fin under the second portions of the dummy gate are removed, wherein the first portions of the dummy gate remain after stopping the etching process; and
forming a separation structure in the recess, wherein the remaining first portions of the dummy gate structure separate portions of the separation structure from the source/drain region, and wherein the remaining portions protrude from the dummy gate spacers into the separation structure with a distance in plan view in a range from 1 nm to 100 nm.

17. The method of claim 16, further comprising forming a dummy gate dielectric over the fin.

18. The method of claim 16, wherein the remaining portions of the dummy gate material comprise silicon, silicon oxide, silicon nitride, or a combination thereof.

19. The method of claim 16, wherein the remaining portions of the dummy gate structure are triangle shaped.

20. The method of claim 19, wherein a ratio of a width of the separation structure to a base width of the triangle shaped remaining portion of the dummy gate structure is in a range from 0.03 to 600.
